(19) United States
(12) Patent Application Publication
(10) Pub. No.: US 2006/0125670 A1
(43) Pub. Date: Jun. 15, 2006

(54) Current cell and digital-to-analog converter using the same

(76) Inventors: Min Hyung Cho, Daejeon (KR); Seung Chul Lee, Daejeon (KR); Chong Ki Kwon, Daejeon (KR); Jong Dae Kim, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/253,181

(22) Filed: Oct. 18, 2005

(30) Foreign Application Priority Data
Dec. 9, 2004 (KR) 2004-103705

(51) Int. Cl. H03M 1/66

(52) U.S. Cl. 341/144

(57) ABSTRACT

Provided are a current cell and digital-to-analog converter (DAC) using the same. The current cell includes a current source; a first transistor transmitting a current produced from the current source to a first output node based on a first signal; a second transistor transmitting a current produced from the current source to a second output node based on a second signal; a first capacitor coupled between a gate of the first transistor and the second output node; and a second capacitor coupled between a gate of the second transistor and the first output node. A current mode DAC can improve in dynamic performance by using a plurality of current cells each having the above-described configuration.

### CROSS-REFERENCE TO RELATED APPLICATION

This application claims priority to and the benefit of Korean Patent Application No. 2004-103705, filed Dec. 9, 2004, the disclosure of which is incorporated herein by reference in its entirety.

### BACKGROUND

1. Field of the Invention

The present invention relates to a current cell and digital-to-analog converter (DAC) using the same and, more specifically, to a current cell, which can minimize glitches, and current mode DAC using the same.

2. Discussion of Related Art

Generally, a digital-to-analog converter (DAC), which converts a digital signal into an analog signal, may include a various kind of elements, such as resistors, capacitors, and current sources, and have diverse configurations. Such a DAC has different merits and demerits in terms of conversion rate, resolution, and power consumption according to the types of elements.

Among a variety of DAC designs, a current mode DAC has the most suitable configuration for high-speed high-resolution signal conversion. Thus, DACs are mostly designed as a current mode for devices that require high speed and high resolution.

Along with developments in digital signal processing technologies, a signal processing mode in which an analog signal is converted into a digital signal and processed and then the processed signal is converted back to an analog signal has lately been in common use. Also, the amount of processed data is on the increase in a variety of wire and wireless communication systems to which the signal processing mode is applied. In this connection, since the amount of data that requires conversion of digital signals to analog signals is also on the increase, a conventional DAC needs to further improve in performance and operate at higher speed and with higher resolution. In addition, an increment of the amount of processed data in the wire and wireless communication systems leads signals to exhibit wide-band frequency characteristics, thus the conventional DAC needs to get better dynamic performance in order to process wide-band signals.

FIG. 1 shows an example of a conventional current mode DAC. Referring to FIG. 1, the DAC includes a decoder and driver 1 and a plurality of current cells 2. The decoder and driver receives N-bit digital data. The current cells 2 are coupled in parallel to an output terminal (+, −) and transmit currents from respective current sources to the output terminal (+,−) based on signals output from the decoder and driver 1.

Each of the current cells 2 may include NMOS transistors shown in FIG. 2A or PMOS transistors shown in FIG. 2B.

Referring to FIG. 2A, NMOS transistors NM3 and NM4 serve as current sources, each of which produces a certain current, whereas NMOS transistors NM1 and NM2 serve as current switches, each of which is used to selectively transmit the current produced from the current source to the output terminal (+,−).

Referring to FIG. 2B, PMOS transistors PM3 and PM4 serve as current sources, each of which produces a certain current, whereas PMOS transistors PM1 and PM2 serve as current switches, each of which is used to selectively transmit the current produced from the current source to the output terminal (+,−).

However, when the current cells 2 are configured as described above, glitches occur in an output signal due to parasitic capacitor elements present in the NMOS transistors (NM1 and NM2) or PMOS transistors (PM1 and PM2), thus deteriorating the dynamic performance of the DAC.

To solve this problem, a method of filtering glitches included in an output signal by installing a current buffer at an output terminal is taught in U.S. Pat. No. 6,741,195 entitled “Low Glitch Current Steering Digital to Analog Converter and Method,” which is filed on May 25, 2004 and assigned to Micron Technology.

Also, U.S. Pat. No. 6,664,906 entitled “Apparatus for Reduced Glitch Energy in Digital to Analog Converter,” which is filed on Dec. 16, 2003 and assigned to Intel Corporation, discusses a technique of removing glitch elements included in an output signal by controlling the on/off time of a current switch.

Tien-Yu Wu proposes a technique of minimizing glitches using a driving circuit for controlling the on/off time of a current switch [“A Low Glitch 10 bit 75 MHz CMOS Video DAC”, JSSC, Vol. 30, pp. 68-72, 1995].

Further, Bruce J. Tesch introduces a technique of preventing a variation in glitches relative to temperature [“A Low Glitch 14 bit 100 MHz DAC”, JSSC, Vol. 32, pp. 1465-1469, 1997].

### SUMMARY OF THE INVENTION

The present invention is directed to a current cell, which can minimize the influence of glitches, and a digital-to-analog converter (DAC) using the current cell, which can improve in dynamic performance.

One aspect of the present invention is to provide a current cell including a current source; a first transistor transmitting a current produced from the current source to a first output node based on a first signal; a second transistor transmitting a current produced from the current source to a second output node based on a second signal; a first capacitor coupled between a gate of the first transistor and the second output node; and a second capacitor coupled between a gate of the second transistor and the first output node.

Another aspect of the present invention is to provide a digital-to-analog converter including a decoder and driver receiving N-bit digital data; and a plurality of current cells transmitting currents produced from each current source to a first output terminal and a second output terminal based on a signal output from the decoder and driver. Each of the current cells includes the current source; a first transistor transmitting a current produced from the current source to the first output terminal based on a first signal; a second transistor transmitting a current produced from the current source to the second output terminal based on a second signal; a first capacitor coupled between a gate of the first transistor and the second output terminal; and a second capacitor coupled between a gate of the second transistor and the first output terminal.

Each of the first and second capacitors may be equal in size to a parasitic capacitor present between the gate and a drain of each of the first and second transistors. For this, each of the first and second capacitors may be comprised of a transistor, which is equal in size to each of the first and second transistors.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a circuit diagram of a conventional current mode digital-to-analog converter (DAC);

FIGS. 2A and 2B are detailed circuit diagrams of a current cell shown in FIG. 1;

FIG. 3A is a circuit diagram for explaining the cause of a glitch generated in a current cell;

FIG. 3B is a signal waveform diagram for explaining the circuit diagram of FIG. 3A;

FIG. 4 is a circuit diagram for explaining the principle on which a glitch is removed according to the present invention;

FIGS. 5 and 6 are circuit diagrams of a current cell according to the present invention; and

FIGS. 7 and 8 are circuit diagrams of a DAC using current cells according to the present invention.

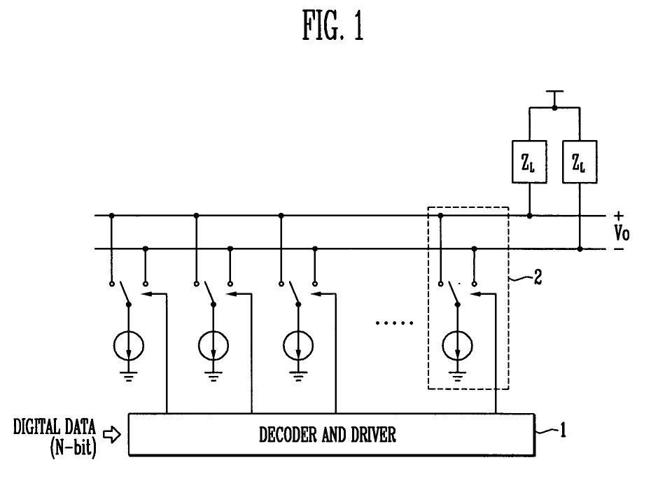

### DETAILED DESCRIPTION OF PREFERRED EMBODIMENTS

The present invention will now be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure is thorough and complete and fully conveys the scope of the invention to those skilled in the art.

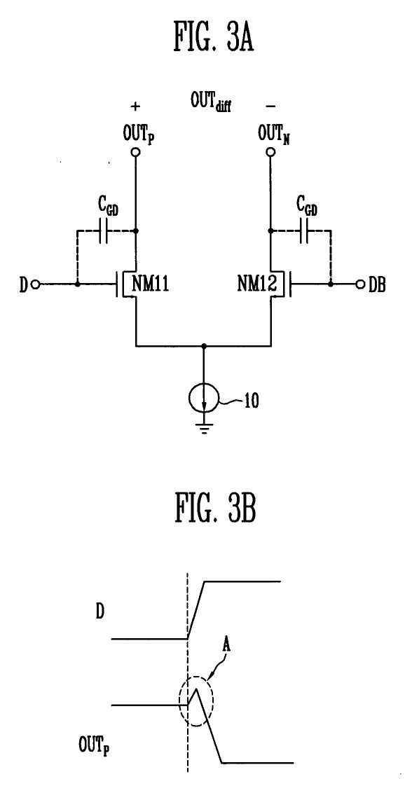

The dynamic characteristics of a current mode digital-to-analog converter (DAC) are constrained by several factors, especially, glitches that occur in current cells. The cause of the glitches and the influence of the glitches on an output signal will now be described with reference to FIGS. 3A and 3B.

FIG. 3A is a circuit diagram of a current cell that is made up of NMOS transistors NM11 and NM12. Referring to FIG. 3A, the current cell includes a current source 10 and the NMOS transistors NM11 and NM12. The NMOS transistors NM11 and NM12 transmit currents produced from the current source 10 to output nodes OUT_{P} and OUT_{N} based on a switching signal D output from, for example, a decoder.

When the switching signal D having a waveform as shown in FIG. 3B is applied through a gate of the NMOS transistor NM11, an output signal OUT_{P} having a waveform as shown in FIG. 3B is output from the output node OUT_{P}. In this case, an undesired glitch as illustrated with a dotted circle A arises in the output signal OUT_{P}.

Such a phenomenon takes place because the switching signal D appears in the output node OUT_{P} through a parasitic capacitor C_{GD} present between an input node (or the gate) and an output node (or a drain) of the NMOS transistor NM11. The glitch arises only in the output node OUT_{P} but not in the phase-inverted output node OUT_{N}.

Similarly, a glitch arises also in a current cell comprised of PMOS transistors owing to the same phenomenon as in the current cell comprised of the NMOS transistors NM11 and NM12, which can be expressed as shown in the following Equation 1:
OUT_{P}′=OUT_{P}+ΔG
OUT_{N}′=OUT_{N}
OUT_{diff}=OUT_{P}′−OUT_{N}′=(OUT_{P}−OUT_{N})+ΔG [Equation 1]
wherein, OUT_{P} and OUT_{N} denote ideal output signals of respective nodes when there is no glitch, ΔG denotes a glitch signal, OUT_{P}′ and OUT_{N}′ denote output signals of the respective nodes when there is a glitch, and OUT_{diff} denotes a differential output signal.

As can be seen from Equation 1, a glitch generated at one node appears in a differential output signal as it is.

As described above, a glitch generated in a current switch of a current cell affects only one of differential output nodes and appears in a differential output signal of a DAC as it is.

Assuming that the same signal as a glitch signal generated at one of differential output nodes is made to appear also at the other phase-inverted node, glitches occur at the respective nodes but are equal in magnitude and phase from the standpoint of a differential output signal. Accordingly, the glitch signals are not glitches any more but become common-mode signals. This principle can be expressed as shown in the following Equation 2:
OUT_{P}′=OUT_{P}+ΔG
OUT_{N}′=OUT_{N}+ΔG
OUT_{diff}=OUT_{P}′−OUT_{N}′=(OUT_{P}+ΔG)−(OUT_{N}+ΔG)=OUT_{P}−OUT_{N} [Equation 2]

As can be seen from Equation 2, by making glitches having the same magnitude occur at both differential output nodes of a current cell, glitch signals become common-mode signals and counteract each other. As a result, a differential output signal can be obtained without the influence of glitches.

In order that a glitch having the same magnitude as a glitch generated at one node may arise also at the other phase-inverted node as described above, a capacitor C_{CP} should be coupled between the gate of the NMOS transistor NM11 of one node and a drain of the NMOS transistor NM12 of the other node and another capacitor C_{CP} should be coupled between a gate of the NMOS transistor NM12 of one node and the drain of the NMOS transistor NM11 of the other node.

In this configuration, the switching signal D applied to the gate of the NMOS transistor NM11 appears as a glitch signal at the output node OUT_{P} through the parasitic capacitor C_{GD} and also appears as a glitch signal at the opposite output node OUT_{N} through the capacitor C_{CP} at the same time. In this case, if the capacitor C_{CP} is equal in size to the parasitic capacitor C_{GN} of the NMOS transistor NM11, glitches generated at the differential output nodes OUT_{P} and OUT_{N} become equal in magnitude. Therefore, glitch noises generated at the differential output nodes OUT_{P} and OUT_{N} become common-mode signals and counteract each other, so they do not adversely affect the differential-mode output signal OUT_{diff}=OUT_{P}−OUT_{N}. The configuration of a current mode DAC using the above-described current cells leads to a reduction in glitches and an improvement in the dynamic performance of the DAC.

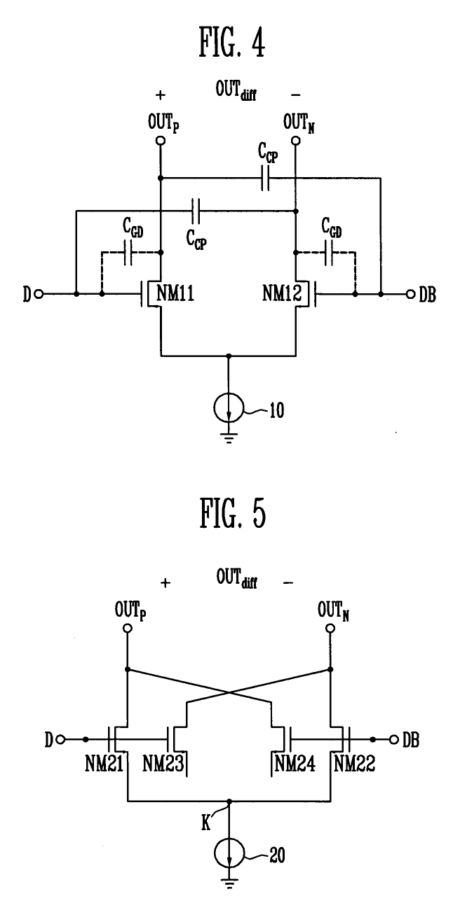

When the capacitor C_{CP} is added as shown in FIG. 4 to create the foregoing common-mode noises, the added capacitor C_{CP} must be equal in size to the parasitic capacitor C_{GD} present between the gate and drain of each of the NMOS transistors NM11 and NM12. Accordingly, the present invention makes use of an NMOS transistor having the same size as each of the NMOS transistors NM11 and NM12 in order that the capacitor C_{CP} may be equal in size to the parasitic capacitor C_{GD}.

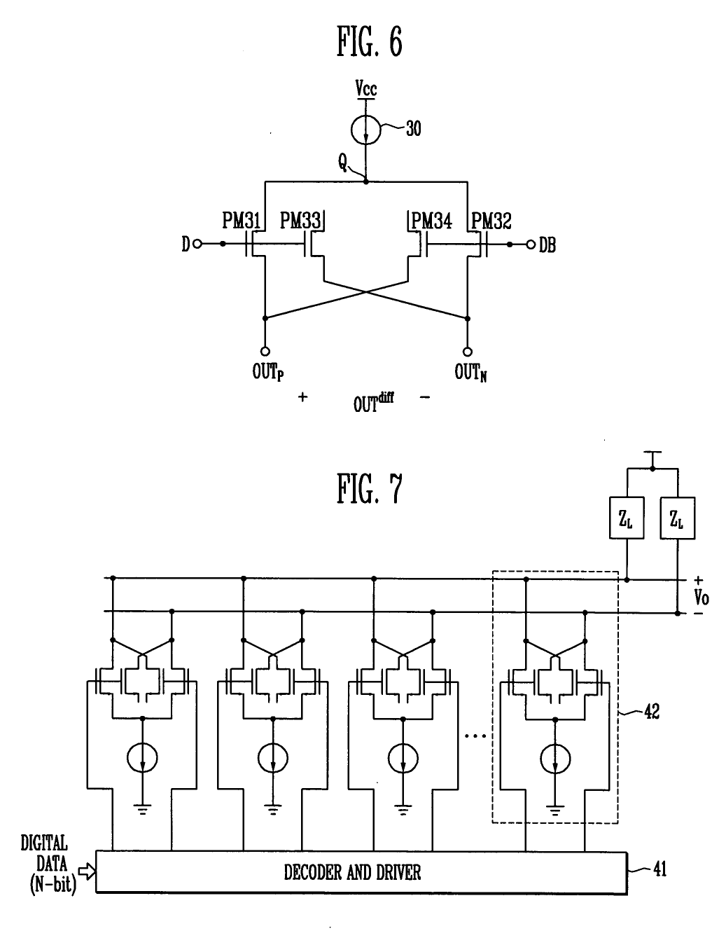

FIGS. 5 and 6 are circuit diagrams of a current cell according to the present invention. Specifically, FIG. 5 illustrates an example of a current cell comprised of NMOS transistors, and FIG. 6 illustrates an example of a current cell comprised of PMOS transistors.

Referring to FIG. 5, a current source 20 is coupled between a node K and a ground voltage. An NMOS transistor NM21 is coupled between the node K and an output node OUT_{P}, and an NMOS transistor NM22 is coupled between the node K and an output node OUT_{N}. The NMOS transistor NM21 receives a switching signal D through a gate thereof, and the NMOS transistor NM22 receives a phase-inverted switching signal DB through a gate thereof. Also, an NMOS transistor NM23 is coupled to the output node OUT_{N}, and an NMOS transistor NM24 is coupled to the output node OUT_{P}. The NMOS transistor NM23 has a gate coupled to the gate of the NMOS transistor NM21, and the NMOS transistor NM24 has a gate coupled to the gate of the NMOS transistor 22.

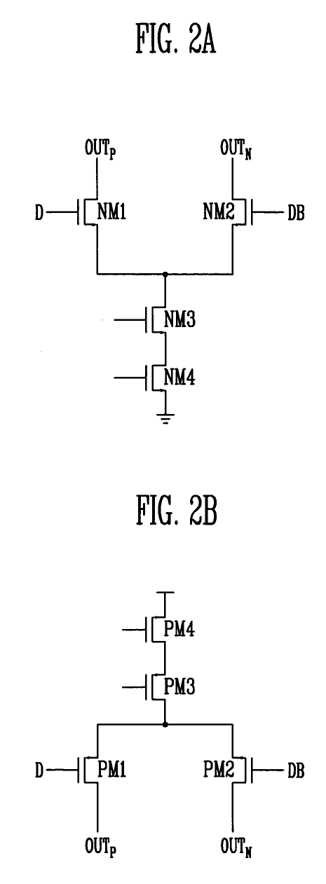

The NMOS transistors NM21, NM22, NM23, and NM24 have the same size so that a capacitor C_{CP} required for causing common-mode noises can be equal in size to a parasitic capacitor C_{GD} present in each NMOS transistor. Also, the current source 20 may be comprised of NMOS transistors as shown in FIG. 2A.

Referring to FIG. 6, a current source 30 is coupled between a node Q and a power supply voltage Vcc. A PMOS transistor PM31 is coupled between the node Q and an output node OUT_{P}, and a PMOS transistor PM32 is coupled between the node Q and an output node OUT_{N}. The PMOS transistor PM31 receives a switching signal D through a gate thereof, and the PMOS transistor PM32 receives a phase-inverted switching signal DB through a gate thereof. Also, a PMOS transistor PM33 is coupled to the output node OUT_{N}, and a PMOS transistor PM34 is coupled to the output node OUT_{P}. The PMOS transistor PM33 has a gate coupled to the gate of the PMOS transistor PM31, and the PMOS transistor PM34 has a gate coupled to the gate of the PMOS transistor PM32.

The PMOS transistors PM31, PM32, PM33, and PM34 have the same size so that a capacitor C_{CP} for causing common-mode noises can be equal in size to a parasitic capacitor C_{GD} present in each PMOS transistor. Also, the current source 30 may be comprised of PMOS transistors as shown in FIG. 2B.

When the current cell includes the NMOS transistors NM21, NM22, NM23, and NM24 as shown in FIG. 5, a glitch caused by the switching signal D is transmitted to the output node OUT_{P} through the parasitic capacitor C_{GD} present between the gate and a drain of the NMOS transistor NM21 and also transmitted to the output node OUT_{N} through the capacitor C_{CP} between the gate and a drain of the NMOS transistor NM23 at the same time. Also, a glitch caused by the phase-inverted switching signal DB is transmitted to the output node OUT_{N} through the parasitic capacitor C_{GD} present between the gate and a drain of the NMOS transistor NM22 and also transmitted to the output node OUT_{P} through the capacitor C_{CP} present between the gate and a drain of the NMOS transistor NM24 at the same time. As a result, a glitch generated at the output node OUT_{P} is equal in magnitude to a glitch generated at the output node OUT_{N}.

Even if the current cell is comprised of the PMOS transistors PM31, PM32, PM33, and PM34 as shown in FIG. 6, the same effect can be obtained by the same operation as described above.

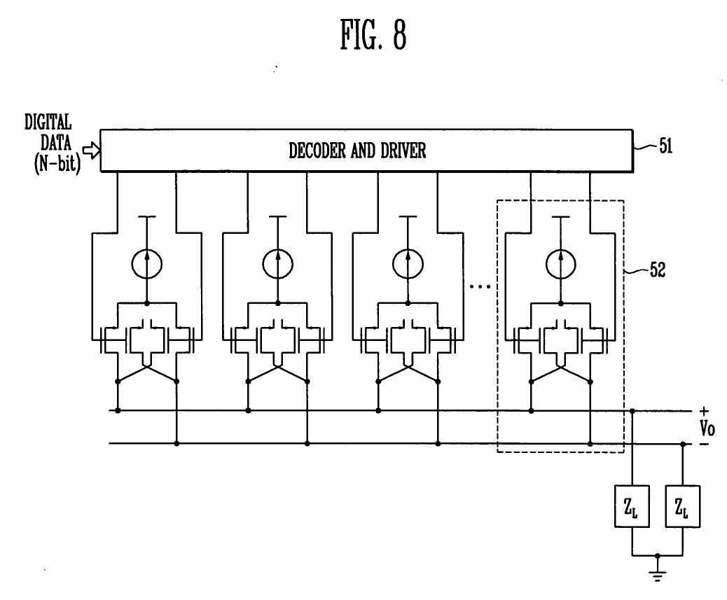

FIGS. 7 and 8 are circuit diagrams of a current mode DAC using current cells according to the present invention. Specifically, FIG. 7 illustrates an example of a DAC using current cells each comprised of NMOS transistors as shown in FIG. 5, and FIG. 8 illustrates an example of a DAC using current cells each comprised of PMOS transistors as shown in FIG. 6.

Referring to FIG. 7, a current mode DAC includes a decoder and driver 41 and a plurality of current cells 42. The decoder and driver 41 receives N-bit digital data. The current cells 42 are coupled in parallel to an output terminal (+,−) and transmit currents produced from respective current sources to the output terminal (+,−) based on a signal output from the decoder and driver 41. Since the configuration of each of the current cells 42 is the same as described with reference to FIG. 5, it will not be explained here again.

Referring to FIG. 8, a current mode DAC includes a decoder and driver 51 and a plurality of current cells 52. The decoder and driver 51 receives N-bit digital data. The current cells 52 are coupled in parallel to an output terminal (+,−) and transmit currents produced from respective current sources to the output terminal (+,−) based on a signal output from the decoder and driver 51. Since the configuration of each of the current cells 52 is the same as described with reference to FIG. 6, it will not be explained here again.

According to the present invention as explained thus far, glitches having the same magnitude are generated at both differential output nodes of a current cell so that a differential output signal freed from the influence of glitches can be obtained owing to the counteraction between common-mode signals. In conclusion, a current mode DAC using current cells according to the present invention can improve in dynamic performance.

In the drawings and specification, there have been disclosed typical preferred embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A current cell comprising:
a current source;
a first transistor transmitting a current produced from the current source to a first output node based on a first signal;
a second transistor transmitting a current produced from the current source to a second output node based on a second signal;
a first capacitor coupled between a gate of the first transistor and the second output node; and
a second capacitor coupled between a gate of the second transistor and the first output node.

2. The current cell according to claim 1, wherein each of the first and second capacitors is equal in size to a parasitic capacitor present between the gate and a drain of each of the first and second transistors.

3. The current cell according to claim 1, wherein each of the first and second capacitors is comprised of a transistor.

4. The current cell according to claim 3, wherein the transistor is equal in size to each of the first and second transistors.

5. A digital-to-analog converter comprising:
a decoder and driver receiving N-bit digital data; and
a plurality of current cells each transmitting currents produced from a current source to a first output terminal and a second output terminal based on a signal output from the decoder and driver,
wherein each of the current cells includes:
the current source;
a first transistor transmitting a current produced from the current source to the first output terminal based on a first signal;
a second transistor transmitting a current produced from the current source to the second output terminal based on a second signal;
a first capacitor coupled between a gate of the first transistor and the second output terminal; and
a second capacitor coupled between a gate of the second transistor and the first output terminal.

6. The digital-to-analog converter according to claim 5, wherein each of the first and second capacitors is equal in size to a parasitic capacitor present between the gate and a drain of each of the first and second transistors.

7. The digital-to-analog converter according to claim 5, wherein each of the first and second capacitors is comprised of a transistor.

8. The digital-to-analog converter according to claim 7, wherein the transistor is equal in size to each of the first and second transistors.
